(19) United States
(12) Patent Application Publication
(10) Pub. No.: US 2014/0291623 A1
(43) Pub. Date: Oct. 2, 2014

(54) ORGANIC LIGHT EMITTING DIODE DISPLAY AND METHOD FOR MANUFACTURING ORGANIC LIGHT EMITTING DIODE DISPLAY

(71) Applicant: SAMSUNG DISPLAY CO., LTD., Yongin-City (KR)

(72) Inventor: Jung-Ho Choi, Yongin-City (KR)

(21) Appl. No.: 13/954,876

(22) Filed: Jul. 30, 2013

(30) Foreign Application Priority Data
Apr. 2, 2013 (KR) 10-2013-0035985

(51) Int. Cl. H01L 51/52; H01L 51/56

(52) U.S. Cl. CPC H01L 51/5203; H01L 51/56
USPC 257/40; 438/34

(57) ABSTRACT

An organic light emitting diode display includes: a substrate; a first electrode on the substrate; a pixel definition layer having opening regions exposing the first electrode; a spacer on the pixel definition layer; a blocking layer between the pixel definition layer and the spacer, the blocking layer having a higher density than the pixel definition layer and the spacer; an organic emission layer on the first electrode in a region of the first electrode corresponding to the opening regions; and a second electrode on the organic emission layer.

### CROSS-REFERENCE TO RELATED APPLICATION

This application claims priority to and the benefit of Korean Patent Application No. 10-2013-0035985 filed in the Korean Intellectual Property Office on Apr. 2, 2013, the entire content of which is incorporated herein by reference.

### BACKGROUND

1. Field

Aspects of embodiments of the present invention relate generally to an organic light emitting diode display and a method for manufacturing an organic light emitting diode display, and more particularly to, an organic light emitting diode display including a pixel definition layer defining a pixel and a method for manufacturing an organic light emitting diode display.

2. Description of the Related Art

A display device is a device that displays an image. Recently, an organic light emitting diode display has been drawing attention.

The organic light emitting diode display has self luminous characteristics and does not require a separate light source, unlike a liquid crystal display device, and thus can have reduced thickness and weight. Further, the organic light emitting diode display represents high quality characteristics such as low power consumption, high luminance, and high response speed.

A conventional organic light emitting diode display includes a pixel circuit including a thin film transistor, a first electrode connected to the pixel circuit, a pixel definition layer exposing the first electrode, a spacer disposed on the pixel definition layer, an organic emission layer disposed on the pixel definition layer, and a second electrode disposed on the organic emission layer.

The organic emission layer of the conventional organic light emitting diode display is formed by placing a mask in contact with the spacer and depositing an organic material on the first electrode through the mask.

However, because a part of the spacer is damaged by interference from the mask by placing the mask used to form the organic emission layer in contact with the spacer, the above-described conventional organic light emitting diode display may have defects caused by the penetration of external moisture into the organic emission layer or the pixel circuit through the damaged part of the spacer.

The above information disclosed in this Background section is only for enhancement of understanding of the background of the described technology and therefore it may contain information that does not form the prior art that is already known in this country to a person of ordinary skill in the art.

### SUMMARY

An exemplary embodiment provides an organic light emitting diode display which suppresses external moisture penetration and a method for manufacturing an organic light emitting diode display.

A first exemplary embodiment provides an organic light emitting diode display including: a substrate; a first electrode on the substrate; a pixel definition layer having opening regions exposing the first electrode; a spacer on the pixel definition layer; a blocking layer between the pixel definition layer and the spacer, the blocking layer having a higher density than the pixel definition layer and the spacer; an organic emission layer on the first electrode in a region of the first electrode corresponding to the opening regions; and a second electrode on the organic emission layer.

The pixel definition layer and the spacer each may include an organic material.

The blocking layer may include an inorganic material.

The blocking layer may include a metal material.

The blocking layer may include an amorphous material.

The blocking layer may contact with the pixel definition layer and the spacer.

A second exemplary embodiment provides a method for manufacturing an organic light emitting diode display, the method including: forming a first electrode on a substrate; forming a pixel definition layer having opening regions exposing the first electrode on the substrate; forming a base blocking layer on the pixel definition layer over the entire substrate, the base blocking layer having a higher density than the pixel definition layer; forming a spacer on the base blocking layer in regions corresponding to the pixel definition layer; etching the base blocking layer using the spacer as a mask to form a blocking layer; placing a pattern mask in contact with the spacer, the pattern mask including an opening pattern corresponding to the opening regions, and depositing an organic emission layer on the first electrode through the opening pattern; and forming a second electrode on the organic emission layer.

The forming the pixel definition layer and the forming the spacer may each be performed by coating a photosensitive organic material on the substrate and exposing and developing the photosensitive organic material.

The forming the base blocking layer may be performed by forming an inorganic material over the entire substrate.

The forming the base blocking layer may be performed by forming a metal material over the entire substrate.

The forming the base blocking layer may be performed by forming an amorphous material over the entire substrate.

According to one of the above-described exemplary embodiments of means for solving the problems addressed by the present invention, there are provided an organic light emitting diode display which suppresses external moisture penetration and a method for manufacturing an organic light emitting diode display.

### BRIEF DESCRIPTION OF THE DRAWINGS

FIG. 1 is a flowchart showing a method for manufacturing an organic light emitting diode display in accordance with a first exemplary embodiment of the present invention.

FIGS. 2, 3, 4, and 5 are cross-sectional views illustrating the method for manufacturing an organic light emitting diode display in accordance with the first exemplary embodiment.

FIG. 6 is a cross-sectional view of an organic light emitting diode display in accordance with a second exemplary embodiment of the present invention.

### DETAILED DESCRIPTION

In the following detailed description, only certain exemplary embodiments have been shown and described, simply by way of illustration. As those skilled in the art would realize, the described embodiments may be modified in various different ways, all without departing from the spirit or scope of the present invention.

In describing the present invention, description of parts that are not related to the description of aspects of the present invention will be omitted. Like reference numerals generally designate like elements throughout the specification.

Furthermore, as the size and thickness of the respective structural components shown in the drawings are arbitrarily illustrated for explanatory convenience, embodiments of the present invention are not necessarily limited to the illustrated sizes and thicknesses.

In the drawings, the thickness of layers, films, panels, regions, etc., are exaggerated for clarity. In the drawings, for understanding and ease of description, the thicknesses of some layers and areas are exaggerated. It will be understood that when an element such as a layer, film, region, or substrate is referred to as being “on” another element, it can be directly on the other element or one or more intervening elements may also be present therebetween, unless otherwise specified.

In addition, unless explicitly described to the contrary, the word “comprise” and variations such as “comprises” or “comprising”, will be understood to imply the inclusion of stated elements but not the exclusion of any other elements. In addition, throughout the specification, “on” implies being positioned above or below a target element, and does not necessarily imply being positioned on top based on, for example, a gravitational direction.

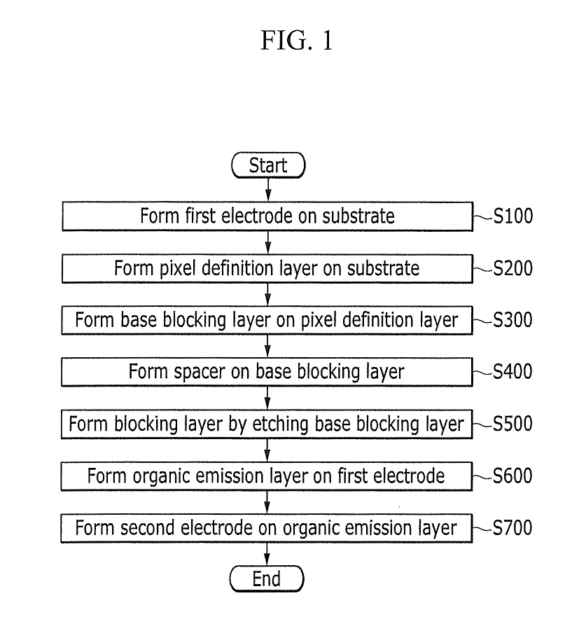

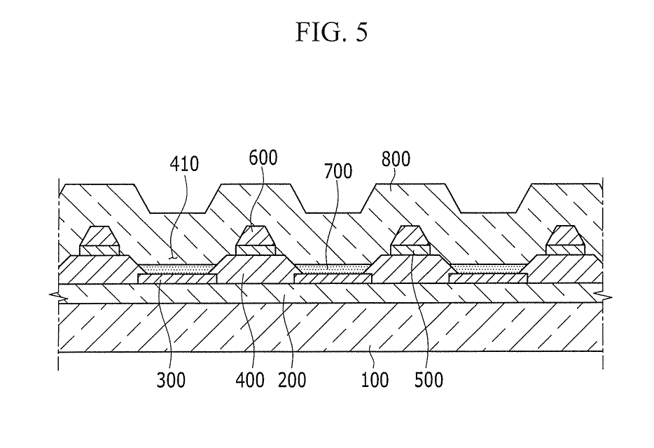

Hereinafter, a method for manufacturing an organic light emitting diode display in accordance with a first exemplary embodiment will be described with reference to FIGS. 1, 2, 3, 4, and 5.

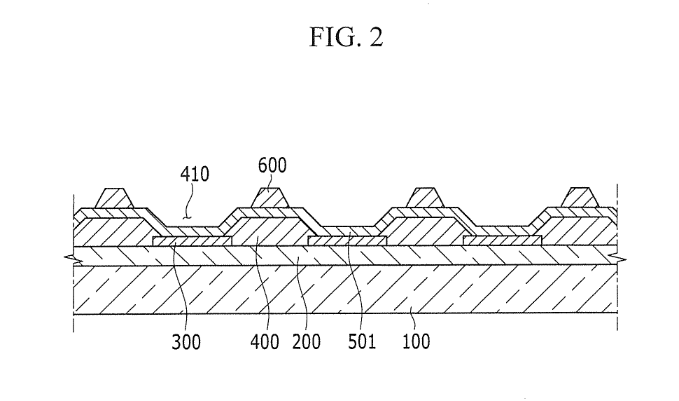

FIG. 1 is a flowchart showing a method for manufacturing an organic light emitting diode display in accordance with a first exemplary embodiment. FIGS. 2, 3, 4, and FIG. 5 are cross-sectional views for explaining the method for manufacturing an organic light emitting diode display in accordance with the first exemplary embodiment.

First of all, as shown in FIG. 1 and FIG. 2, a first electrode 300 is formed on a substrate 100 (S100).

In more detail, a pixel circuit 200 is formed on the substrate 100 formed as an insulating substrate made of glass, quartz, ceramic, plastic, etc. The pixel circuit 200 may include a pixel line including at least one scan line, at least one data line, and at least one driving power line, two or more thin film transistors TFTs connected to the pixel line so as to correspond to one pixel, and at least one capacitor. The pixel circuit 200 may have various known structures. Herein, the pixel refers to a fundamental (or minimum) unit displaying an image, and the organic light emitting diode display displays an image using a plurality of pixels. The pixel circuit 200 may be formed by using a MEMS technology such as photolithography.

The first electrode 300 connected to the thin film transistors is formed on the pixel circuit 200. The first electrode 300 may correspond to one pixel, and a plurality of parts of the first electrode 300 are spaced apart from each other on the pixel circuit 200.

A pixel definition layer 400 is formed on the substrate 100 (S200).

In more detail, a pixel definition layer 400 including opening regions 410 exposing the first electrode 300 is formed on the substrate 100 to cover edge portions of the first electrode 300. The pixel definition layer 400 may be formed by coating a first organic layer including a photosensitive organic material on the substrate 100, exposing the first organic layer including the photosensitive organic material by a light transmissive mask, and then developing the exposed first organic layer.

A base blocking layer 501 is formed on the pixel definition layer 400 (S300).

In more detail, a base blocking layer 501 having a higher density than the pixel definition layer 400 is formed on the pixel definition layer 400 over the entire substrate 100. The base blocking layer 501 may include a material having a higher density than the photosensitive organic material included in the pixel definition layer 400. The base blocking layer 501 may include an inorganic material, a metal material, or an amorphous material.

For example, the base blocking layer 501 may be formed by depositing an inorganic material such as silicon nitride or silicon oxide over the entire substrate 100.

In another example, the base blocking layer 501 may be formed by depositing a metal material such as aluminum or titanium over the entire substrate 100.

In still another example, the base blocking layer 501 may be formed by depositing an amorphous material such as glass, quartz, amorphous silicon, or amorphous oxide over the entire substrate 100.

A spacer 600 is formed on the base blocking layer 501 (S400).

In more detail, a spacer 600 is formed on the base blocking layer 501 so as to correspond to the pixel definition layer 400. The spacer 600 may be formed by coating a second organic layer including a photosensitive organic material on the base blocking layer 501, exposing the second organic layer including the photosensitive organic material by a light transmissive mask, and then developing the exposed second organic layer. The spacer 600 includes a photosensitive organic material having a lower density than the base blocking layer 501.

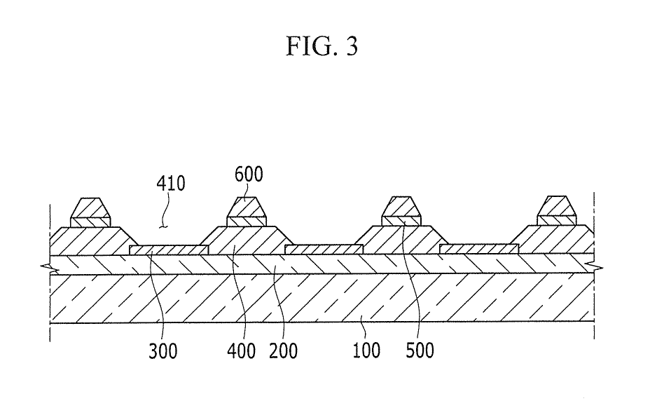

Referring to FIG. 3, a blocking layer 500 is formed by etching the base blocking layer 501 (S500).

In more detail, a blocking layer 500 is formed by etching the base blocking layer 501 by using the spacer 600 as a mask. The blocking layer 500 may be formed by wet-etching or dry-etching the base blocking layer 501 by using the spacer 600 as a mask. The blocking layer 500 has a higher density than the pixel definition layer 400 including an organic material and the spacer 600, and may include an inorganic material, a metal material, or an amorphous material depending on what material the base blocking layer 501 includes (e.g., the material used to form the base blocking layer 501).

Alternatively, the blocking layer 500 may be formed by placing an additional mask on the spacer 600 and etching the base blocking layer 501 using the additional mask.

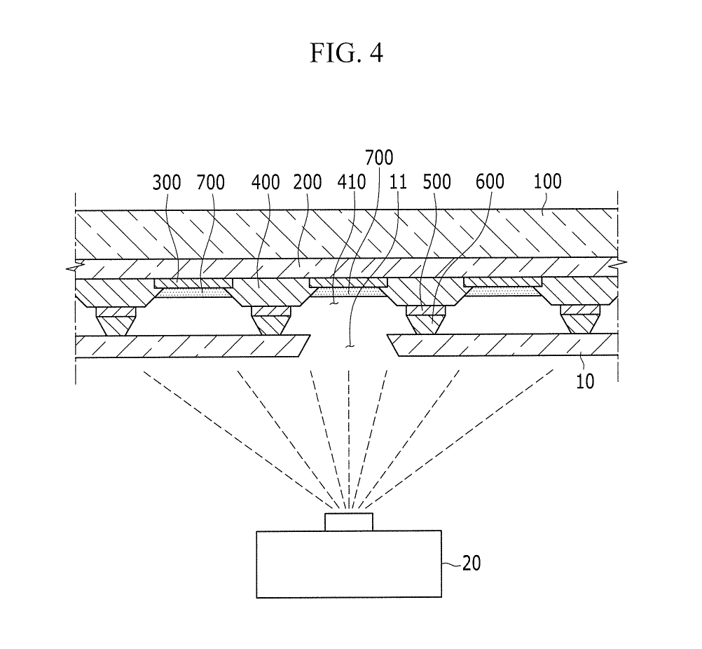

Referring to FIG. 4, an organic emission layer 700 is formed on the first electrode 300 (S600).

In more detail, a pattern mask 10 including an opening pattern (or opening) 11 corresponding to an opening region 410 is placed in contact with the spacer 600, and an organic emission layer 700 is formed on the first electrode 300 through the opening pattern 11. The organic emission layer 700 may be formed by placing the pattern mask 10 in contact with the spacer 600, and then depositing an organic phosphorous material from a deposition source 20 onto the first electrode 300 thorough the opening pattern 11 of the pattern mask 10. The pattern mask 10 may include the opening pattern 11 corresponding to the opening region 410 exposing a selected one of the plurality of parts of the first electrode 300.

In this manner, the organic emission layer 700 is deposited when the pattern mask 10 is in contact with the spacer 600. Therefore, the spacer 600 blocks or prevents an organic emitting material from being deposited on parts of the first electrode 300 other than a target part of the first electrode 300 through the opening pattern 11. That is, deposition of an organic emitting material onto an undesired (or unintended) area is suppressed by the spacer 600.

Moreover, the pattern mask 10 is easily mounted onto the substrate 100 for depositing the organic emission layer 700 when the pattern mask 10 is in contact with the spacer 600, thereby suppressing errors in the deposition of the entire organic emission layer 700.

A second electrode 800 is formed on the organic emission layer 700 (S700).

In more detail, a second electrode 800 is formed over the entire substrate 100 so that the second electrode 800 is formed on the organic emission layer 700.

A thin film encapsulation layer, along with the substrate 100, may be formed on the second electrode 800 to seal the organic light emitting diode OWED.

An organic light emitting diode display in accordance with a second exemplary embodiment to be described below can be manufactured by the above procedure.

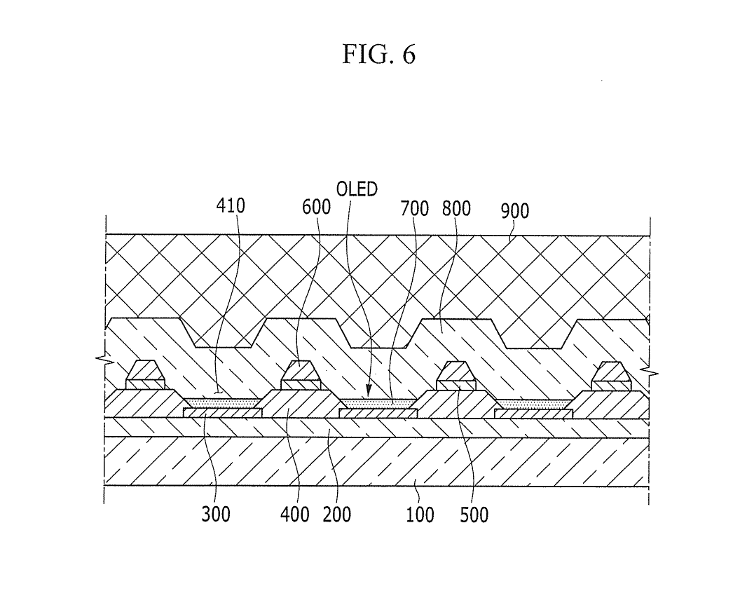

Now, the organic light emitting diode display in accordance with the second exemplary embodiment will be described with reference to FIG. 6.

FIG. 6 is a cross-sectional view showing the organic light emitting diode display in accordance with the second exemplary embodiment.

As shown in FIG. 6, the organic light emitting diode display in accordance with the second exemplary embodiment includes a substrate 100, a pixel circuit 200, an organic light emitting diode OLED, a pixel definition layer 400, a spacer 600, a blocking layer 500, and a thin film encapsulation layer 900.

The substrate 100 is formed as an insulating substrate made of glass, quartz, ceramic, metal, plastic, etc. Moreover, if the substrate 100 is made of plastic or the like, the organic light emitting diode display may be flexible, stretchable, or rollable.

The pixel circuit 200 is disposed on the substrate 100, and may include a pixel line (or pixel area) including at least one scan line, at least one data line, and at least driving power line, two or more thin film transistors connected to the pixel line so as to correspond to one pixel, and at least one capacitor. The pixel circuit 200 may have various known structures.

The organic light emitting diode OLED includes a first electrode 300, an organic emission layer 700, and a second electrode 800.

The first electrode 300 is disposed on the pixel circuit 200, and connected to the thin film transistors of the pixel circuit 200. Edge portions of the first electrode 300 are covered by the pixel definition layer 400.

Either the first electrode 300 or the second electrode 800 may be an anode functioning as a hole injection electrode, and the other one may be a cathode functioning as an electron injection electrode. At least one of the first electrode 300 and the second electrode 800 is formed as a light transmissive electrode, and light emitted from the organic emission layer 700 may be emitted toward one of the first electrode 300 and the second electrode 800.

The organic emission layer 700 may emit at least one of red, green, blue, and white light. If the organic emission layer 700 emits white light, a color filter for converting (or filtering) the wavelength of light may be disposed on the path of light emitted from the organic emission layer 700.

The pixel definition layer 400 includes opening regions 410 exposing some portions of the first electrode 300 where the organic emission layer 700 is disposed. The pixel definition layer 400 protrudes upward and defines the opening regions 410. The pixel definition layer 400 includes an organic material having a lower density than the blocking layer 500.

The spacer 600 is disposed on the pixel definition layer 400, and has a smaller area than the pixel definition layer 400. The spacer 600 protrudes upward. The spacer 600 includes an organic material having a lower density than the blocking layer 500.

The blocking layer 500 is disposed between the pixel definition layer 400 and the spacer 600, and contacts the pixel definition layer 400 and the spacer 600. The blocking layer 500 includes a different material from those of the pixel definition layer 400 and the spacer 600. The blocking layer 500 may include an inorganic material such as silicon nitride or silicon oxide, a metal material such as aluminum or titanium, and an amorphous material such as glass, quartz, amorphous silicon, or amorphous oxide. The blocking 500 may have substantially the same area as the bottom surface of the spacer 600. The blocking layer 500 may have a thickness greater than 500 Å.

As the blocking layer 500 disposed between the pixel definition layer 400 and the spacer 600 has a higher density than the pixel definition layer 400 and the spacer 600, moisture penetrating from the outside through the spacer 600 is blocked by the blocking layer 500, thereby preventing or blocking the moisture from moving to the pixel definition layer 400.

The thin film encapsulation layer 900, along with the substrate 100, seals the organic light emitting diode OLED and protects the organic light emitting diode OLED from moisture penetrating from the outside and external interference. The thin film encapsulation layer 900 may include at least one organic layer and at least one inorganic layer, and a plurality of organic layers and a plurality of inorganic layers may be alternately stacked on top of each other.

As seen from above, the method for manufacturing an organic light emitting diode display in accordance with the first exemplary embodiment and the organic light emitting diode display in accordance with the second exemplary embodiment can avoid the deposition of an organic emitting material on undesired areas through the opening pattern of the pattern mask and suppress or reduce errors in the deposition of the organic emission layer 700, because the spacer 600 is placed in contact with the pattern mask during the formation of the organic emission layer 700.

Moreover, the organic light emitting diode display in accordance with the second exemplary embodiment can prevent or block external moisture from penetrating into the pixel circuit 200 and the organic emission layer 700 through the pixel definition layer 400 by forming or including the blocking layer 500 of an inorganic material, metal material, or amorphous material having a higher density than the pixel definition layer 400 and the spacer 600 both including an organic material, because even if a part of the spacer 600 is damaged by interference from the pattern mask in contact with the spacer 600 during the formation of the organic emission layer 700, the blocking layer 500 in contact with the pixel definition layer 400 and the spacer 600 between the pixel definition layer 400 and the spacer 600 prevents or blocks moisture penetrating from the outside through the damaged part of the spacer 600. In other words, there is provided an organic light emitting diode display which suppresses external moisture from penetrating into the pixel circuit 200 and the organic emission layer 700 through the pixel definition layer 400, even if the spacer 600 is damaged by the pattern mask.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and equivalents thereof.

### Description of Selected Reference Numerals

substrate 100,
first electrode 300,
pixel definition layer 400,
spacer 600,
blocking layer 500,
organic emission layer 700,
second electrode 800

What is claimed is:

1. An organic light emitting diode display comprising:
a substrate;
a first electrode on the substrate;
a pixel definition layer having opening regions exposing the first electrode;
a spacer on the pixel definition layer;
a blocking layer between the pixel definition layer and the spacer, the blocking layer having a higher density than the pixel definition layer and the spacer;
an organic emission layer on the first electrode in a region of the first electrode corresponding to the opening regions; and
a second electrode on the organic emission layer.

2. The organic light emitting diode display of claim 1, wherein the pixel definition layer and the spacer each comprises an organic material.

3. The organic light emitting diode display of claim 2, wherein the blocking layer comprises an inorganic material.

4. The organic light emitting diode display of claim 2, wherein the blocking layer comprises a metal material.

5. The organic light emitting diode display of claim 2, wherein the blocking layer comprises an amorphous material.

6. The organic light emitting diode display of claim 1, wherein the blocking layer contacts the pixel definition layer and the spacer.

7. A method for manufacturing an organic light emitting diode display, the method comprising:
forming a first electrode on a substrate;
forming a pixel definition layer having opening regions exposing the first electrode on the substrate;
forming a base blocking layer on the pixel definition layer over the entire substrate, the base blocking layer having a higher density than the pixel definition layer;
forming a spacer on the base blocking layer in regions corresponding to the pixel definition layer;
etching the base blocking layer using the spacer as a mask to form a blocking layer;
placing a pattern mask in contact with the spacer, the pattern mask including an opening pattern corresponding to the opening regions, and depositing an organic emission layer on the first electrode through the opening pattern; and
forming a second electrode on the organic emission layer.

8. The method of claim 7, wherein the forming the pixel definition layer and the forming the spacer are each performed by coating a photosensitive organic material on the substrate and exposing and developing the photosensitive organic material.

9. The method of claim 8, wherein the forming the base blocking layer is performed by forming an inorganic material over the entire substrate.

10. The method of claim 8, wherein the forming the base blocking layer is performed by forming a metal material over the entire substrate.

11. The method of claim 8, wherein the forming the base blocking layer is performed by forming an amorphous material over the entire substrate.
